(19) United States
(12) Patent Application Publication
(10) Pub. No.: US 2022/0102310 A1
(43) Pub. Date: Mar. 31, 2022

(54) SEMICONDUCTOR DEVICE AND METHOD FOR PRODUCING SAME

(71) Applicant: NAGASE & CO., LTD., Osaka (JP)

(72) Inventors: Michihiro SATO, Oita (JP); Tadashi TAKANO, Columbus, CA (US)

(73) Assignee: NAGASE & CO., LTD., Osaka (JP)

(21) Appl. No.: 17/418,077

(22) PCT Filed: Dec. 13, 2019
(86) PCT No.: PCT/JP2019/048857

§ 371 Date: Jun. 24, 2021

Related U.S. Application Data
(60) Provisional application No. 62/785,993, filed on Dec. 28, 2018.

(51) Int. Cl. H01L 23/00; H01L 23/29; H01L 23/31; H01L 23/538; H01L 23/66; H01L 21/48; H01L 21/56

(52) U.S. Cl. CPC H01L 24/20; H01L 23/291; H01L 23/3121; H01L 23/5383; H01L 23/5386; H01L 23/5389; H01L 2224/214; H01L 24/19; H01L 21/4853; H01L 21/4857; H01L 21/565; H01L 2223/6677; H01L 23/66

(57) ABSTRACT

The occurrence of a positional shift of a semiconductor chip during resin sealing is suppressed; and a redistribution layer is easily and accurately formed. A semiconductor device according to the present invention is provided with: a substrate which is formed of a cured thermosetting resin, and which has one or more recesses; a circuit element which is arranged within a recess of the substrate; and a redistribution layer which is connected to the circuit element on the opening side of the recess.

### TECHNICAL FIELD

The present invention relates to a semiconductor device and a method for producing the same.

### BACKGROUND ART

When producing a semiconductor device, there has conventionally known a technique that arranges a plurality of diced semiconductor chips on a wafer substrate and seals the semiconductor chips with a thermosetting mold resin (Patent Document 1). The semiconductor chip is sealed within an insulating layer by a thermosetting process of the mold resin, which has a problem of an occurrence of a positional shift of the semiconductor chips placed on the wafer due to a shrinkage effect of the resin and a thermal expansion effect of the wafer during the thermosetting process. In the case of employing a process of resin sealing after the semiconductor chips are disposed on the wafer, a chip surface and a mold surface do not always become flush to possibly cause a level difference therebetween, and thus, there lies a problem that the level difference causes various failures when a redistribution layer is formed on the chip surface.

In order to avoid the above-described problem, there has been proposed, for example, a technique that provides a recess on a substrate, three-dimensionally provides wirings on a surface inside the recess, mounts a semiconductor chip on the wirings, and connects electrodes of the semiconductor chip to the wirings (Patent Document 2). Further in the technique of Patent Document 2, the vicinities of the connected positions between the semiconductor chip and the wirings are at least sealed with resin, and external connected portions of the respective wirings are partly exposed.

Patent Document 1: JP-A-2015-053468

Patent Document 2: JP-A-2000-164759

### DISCLOSURE OF THE INVENTION

### Problems to be Solved by the Invention

As in the technique described in Patent Document 2, three-dimensionally providing the wirings (the redistribution layer) from the inside over to the outside of the recess of the substrate is associated with a technical difficulty, and has a problem of causing an increased producing cost and a deterioration in yield. Three-dimensionally forming the wirings lengthens connection paths of the wirings, and therefore, there also is a problem of disadvantageous electric property.

Therefore, one of objectives of the present invention is to provide a semiconductor device that ensures suppressing the occurrence of a positional shift of a semiconductor chip during resin sealing and forming a redistribution layer easily and accurately, and a method for producing the same.

### Solutions to the Problems

A first aspect of the present invention relates to a semiconductor device. The semiconductor device according to the present invention at least includes a substrate, a circuit element, and a redistribution layer. The substrate is formed of a cured thermosetting resin and has one or a plurality of recesses. The circuit element is disposed in the recess of the substrate. Examples of the “circuit element” are a semiconductor chip, such as an LSI, and an electronic element, such as a wireless antenna, an optical sensor, and a resistive element. The redistribution layer is electrically connected to the circuit element on an opening side of the recess. That is, the recess of the substrate is formed of the opening, side surfaces, and a bottom surface, and the redistribution layer is formed on the opening side on an opposite side of the bottom surface among them. The redistribution layer is preferred to be planarly formed.

As in the above-described configuration, the recess is formed on the already-heat-cured substrate, and the circuit element, such as the semiconductor chip, is disposed there in the present invention. In view of this, even when the circuit element is sealed with the thermosetting mold resin, the occurrence of the positional shift of the circuit element caused by the shrinkage effect of the resin during the thermosetting process can be avoided. Since the already-heat-cured one is used for the substrate, an expansion of the substrate during the thermosetting process of the mold resin can be suppressed. Furthermore, planarly forming the redistribution layer on the opening side of the recess eliminates the need for providing a three-dimensional wiring as in the technique of Patent Document 2, thereby ensuring easily and accurately forming the redistribution layer.

Conventionally, the thermosetting resin (the mold resin) is a material that has been developed to mainly seal the circuit element, and, generally, placing the circuit element in a mold and performing the thermosetting process after pushing an uncured thermosetting resin into the mold seals the circuit element inside the resin. The present invention uses the thermosetting resin, not for the usage of sealing the circuit element, but for just forming a base material for disposing the circuit element. Accordingly, in the present invention, the thermosetting resin is used not for the original sealing usage but is used only for forming the substrate (also referred to as a wafer or a panel) with the recess, and curing of the thermosetting resin is completely terminated by a phase where the circuit element is mounted on the substrate. The circuit element disposed on the substrate has its circuit formed by forming the redistribution layer thereafter. When the thermosetting resin is used in a conventional way, as described above, the problem, such as a positional shift of the circuit element, is caused by a shrinkage of the resin associated with curing. The present invention ensures overcoming disadvantage of such a thermosetting resin.

In the semiconductor device according to the present invention, the substrate may have the plurality of recesses having different depths. Thus differentiating the depths of the recesses ensures disposing a plurality of kinds of circuit elements with different thicknesses on the substrate.

In the semiconductor device according to the present invention, one or a plurality of recesses may be formed on both a first surface and a second surface of the substrate. Thus providing the recesses on both the surfaces of the substrate ensures an improved integration of the circuit elements.

In the semiconductor device according to the present invention, at least one of the recesses of the substrate may have its bottom surface formed into a recessed curved surface. Note that, the “curved surface” includes one having a curved surface shaped cross-sectional surface, other than a hemisphere surface or a parabolic-curved surface. In this case, it is preferred that a wireless antenna or an optical sensor is disposed as, for example, the circuit element in the recess having the bottom surface formed into the recessed curved surface. Thus, the bottom surface of the recess of the substrate can be formed into a curved surface shape so as to match the shape of the circuit element disposed there. In particular, disposing the wireless antenna on the bottom surface formed into a recessed curved surface causes the bottom surface to function like a parabola antenna, and the wireless antenna can receive a weak wireless signal at high sensitivity or at a wide angle. Disposing the optical sensor on the bottom surface formed into a recessed curved surface ensures causing the bottom surface to function like a wide-angle lens and also improving detection sensitivity. Furthermore, disposing the optical sensor in the recess of the substrate ensures causing a Chief Ray Angle (CRA) of this sensor to be a small angle, and therefore, ensures achieving a low CRA of, for example, 30 degrees or less with a physical structure of the substrate.

In the semiconductor device according to the present invention, at least one of the recesses of the substrate may have its bottom surface formed into a projected curved surface. In this case, in the recess having the bottom surface formed into a projected curved surface, a wireless antenna or an optical sensor is preferably disposed as the circuit element. Thus, the bottom surface of the recess of the substrate can be formed into a curved surface shape so as to match the shape of the circuit element disposed there. In particular, disposing the wireless antenna on the bottom surface formed into a projected curved surface ensures outputting the wireless signal at a wide angle, and therefore, the number of elements of the wireless antenna disposed there can be reduced. Disposing the optical sensor on the bottom surface formed to be the projected curved surface ensures contributing to an expanded detection area and improved sensitivity.

In the semiconductor device according to the present invention, the substrate may have a conductor material disposed in the recess to such that the conductor material passes through in a thickness direction of the substrate. That is, the substrate may have a hole portion formed in the recess, and the conductor material may be filled inside the hole portion. As the “conductor material”, a material having both or at least one of conductive property and thermal conductivity is used. Thus, providing the hole portion for disposing the circuit element in the recess and disposing the conductor material in the hole portion ensures forming a conduction on a back surface side of the circuit element or ensures efficiently releasing a heat emitted by the circuit element.

In the semiconductor device according to the present invention, the substrate may have the conductor material disposed in a peripheral area of the recess such that the conductor material passes through in the thickness direction of the substrate. Thus, a through-via can be formed in the peripheral area of the recess.

In the semiconductor device according to the present invention, the thermosetting resin before curing preferably has a thermal conductivity of 0.5 W/mk or more. Using the resin having high thermal conductivity of 0.5 w/mk or more ensures effectively discharging the heat generation from the circuit element internally implanted.

In the semiconductor device according to the present invention, the thermosetting resin preferably includes one or two or more of silica, alumina, aluminum nitride, and boron nitride. Thus, an epoxy resin in which one type or two or more types of silica, alumina, aluminum nitride, and boron nitride are filled can cause the thermal conductivity to be 1.2 W/mk or more, thereby ensuring further enhanced generated heat discharging effect.

Another configuration of the semiconductor device according to the present invention will be described. The semiconductor device according to the present invention includes a substrate, a plurality of circuit elements, a redistribution layer, and a through-via. The substrate is formed of a cured thermosetting resin, has a first surface and a second surface, and one or a plurality of recesses are formed on both the first surface and the second surface. The circuit elements are disposed in the respective recesses on both the first surface and the second surface. The redistribution layers are connected to the circuit elements on opening sides of the recesses on both the first surface and the second surface. The through-via is formed to pass through the substrate in a thickness direction in peripheral areas of the recesses. The redistribution layers on the first surface and the second surface are electrically connected via this through-via. Thus, by disposing the circuit elements in the recesses formed on both surfaces of the substrate and connecting each of the circuit elements to the redistribution layer, as well as disposing the through-via in the peripheral area of the recess of the substrate and connecting the redistribution layers on both surfaces of the substrate via this through-via, the circuit elements on both surfaces of the substrate are electrically connected. Accordingly, a degree of integration of the circuit elements can be improved.

A second aspect of the present invention relates to a method for producing a semiconductor device. In the production method according to the present invention, first, a substrate is formed by heat-curing a thermosetting resin after molding the thermosetting resin into a shape having one or a plurality of recesses (a first step). Next, a circuit element is disposed in the recess of the substrate (a second step). Next, a redistribution layer is connected to the circuit element on an opening side of the recess (a third step). In view of this, the semiconductor device according to the first aspect described above can be efficiently produced.

In the production method according to the present invention, in the step of disposing the circuit element, an adhesive agent with insulating property may be disposed in the recess or on the circuit element to join the substrate and the circuit element with the adhesive agent. Note that, the “adhesive agent” referred to herein widely includes, for example, an adhesive member in a film form besides an adhesive agent in a liquid or in a paste. Thus, using the adhesive agent with insulating property for joining the substrate and the circuit element ensures accurately joining the circuit element in the recess of the substrate and simultaneously forming the insulating layer in the peripheral area of the circuit element with the adhesive agent.

In the production method according to the present invention, in the step of disposing the circuit element, an adhesive agent with conductive property may be disposed in the recess or on the circuit element to join the substrate and the circuit element with the adhesive agent. Using the adhesive agent with conductive property for joining the substrate and the circuit element ensures a conduction from the back surface of the circuit element. Using the conductive paste that uses metal powders as the adhesive agent ensures achieving high thermal conductive property to ensure obtaining a satisfactory heat dissipation characteristic.

The production method according to the present invention may further include a step of causing at least one of the recesses to make a through-hole by drilling the substrate from a second surface side on an opposite side of a first surface on which the recess of the substrate is disposed (a fourth step). While as described above, the recess of the substrate can be obtained by molding the thermosetting resin (a compression method and a transfer method), drilling a part of these recesses from the opposite surface side ensures efficiently forming the through-hole (the through-via).

In the production method according to the present invention, the step of forming the substrate may be a step of forming the substrate by heat-curing a thermosetting resin after molding the thermosetting resin into a shape having one or a plurality of recesses and one or a plurality of through-holes. Accordingly, the recess and the through-hole can be simultaneously formed on the substrate.

In the production method according to the present invention, the step of forming the substrate may bring a thermosetting resin into pressure contact with a surface of a plate member having a projecting portion with conductive property, heat-cure the thermosetting resin with the thermosetting resin surrounding a peripheral area of the projecting portion, and cut off a portion excluding the projecting portion of the plate member, so as to cause the projecting portion to function as a through-via passing through the substrate made of the thermosetting resin in a thickness direction. This ensures forming the through-via on the substrate with a simple step.

### Advantageous Effects of the Invention

With the present invention, the occurrence of a positional shift of a semiconductor chip during resin sealing can be suppressed, and a redistribution layer can be easily and accurately formed.

### BRIEF DESCRIPTION OF THE DRAWINGS

FIG. 1 illustrates a cross-sectional structure of a semiconductor device according to a first embodiment.

FIG. 2 illustrates an exemplary production process of a substrate.

FIG. 3 illustrates another exemplary production process of the substrate.

FIG. 4 illustrates an exemplary production process of the semiconductor device.

FIG. 5 illustrates a modification of the semiconductor device according to a first embodiment.

FIG. 6 illustrates a cross-sectional structure of a semiconductor device according to a second embodiment.

FIG. 7 illustrates another exemplary production process of the semiconductor device.

FIG. 8 illustrates a modification of the semiconductor device.

FIG. 9 illustrates a plate member used in the production process of the substrate.

FIG. 10 illustrates a process for producing the substrate using the plate member.

FIG. 11 illustrates the substrate obtained in the process illustrated in FIG. 10.

### DESCRIPTION OF PREFERRED EMBODIMENTS

The following describes embodiments of the present invention using the drawings. The present invention is not limited to the embodiments described below and includes ones appropriately changed in an obvious range by those skilled in the art from the following embodiments.

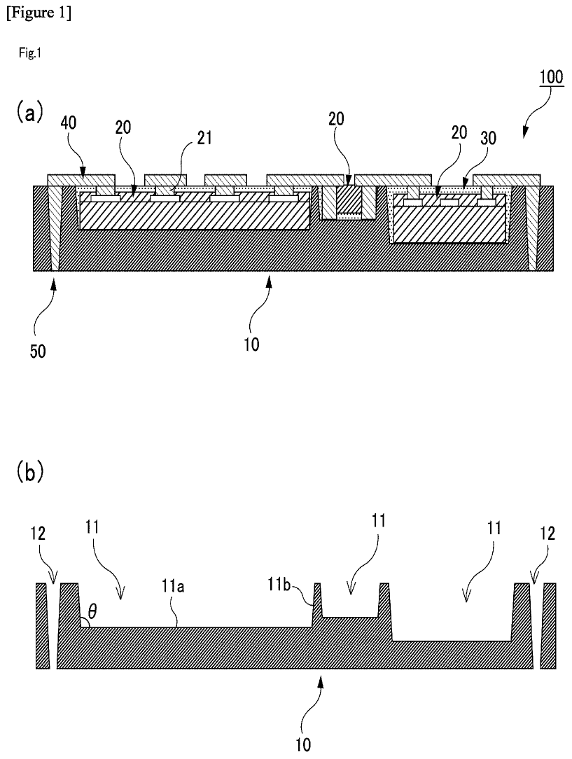

FIG. 1 is a cross-sectional view of a semiconductor device 100 according to a first embodiment of the present invention. As illustrated in FIG. 1, the semiconductor device 100 is a wafer level package configured by including a substrate 10, circuit elements 20, and redistribution layers 40. FIG. 1(a) illustrates a cross-sectional structure of the whole semiconductor device 100, and FIG. 1(b) illustrates a cross-sectional structure of the substrate 10 only.

The substrate 10 can be obtained by performing a thermosetting process after molding an uncured thermosetting resin into a predetermined shape. Accordingly, the substrate 10 is formed of a cured thermosetting resin. As the thermosetting resin, for example, an epoxy resin, a polyimide resin, a phenol resin, a cyanate resin, a polyester resin, an acrylic resin, a bismaleimide resin, a benzoxazine resin, or a mixed resin of one type or two or more types of these can be used.

More specifically describing, as the thermosetting resin that forms the substrate 10, it is preferred to use a material that satisfies the conditions: a glass-transition temperature (Tg) of 125° C. or more (ideally 150° C. or more); a decomposition temperature of 260° C. or more; a room temperature elastic modulus of 500 MPa or more; and a linear expansion coefficient of 60 ppm/° C. or less. Selecting such a material renders the substrate 10 made of the thermosetting resin after curing highly heat resistant, low in linear expansion rate, and high in elastic modulus, thereby ensures obtaining excellent properties compared with a general resin and reducing an introduction cost of the substrate 10 to low. It is also preferred that the thermal conductivity of the uncured thermosetting resin is 0.5 w/mk or more. Using the resin with the high thermal conductivity of 0.5 w/mk or more ensures effectively discharging the generated heat from the circuit element internally implanted. For example, it is possible to cause the thermal conductivity to be 1.2 W/mk or more in an epoxy resin filled with one type or two or more types of silica, alumina, aluminum nitride, and boron nitride.

As illustrated in FIG. 1(b), the substrate 10 has at least one surface side on which one or a plurality of recesses 11 are formed. The recess 11 is configured of a bottom surface 11a and side surfaces 11b that surround its peripheral area, and a part facing the bottom surface 11a opens. In the illustrated example, the substrate 10 has a plurality of positions where the recesses 11 are disposed, and the respective recesses 11 have respectively different depths. As described later, in the respective recesses 11, the circuit elements 20 of, for example, semiconductor chips are disposed, but the depth of the recess 11 is appropriately adjusted corresponding to the thickness of the circuit element 20 disposed there. Disposing the plurality of recesses 11 with different depths on the substrate 10 ensures disposing several kinds of the circuit elements 20 with different thicknesses on one substrate 10. For example, in the case where two adjacent recesses 11 are compared, when the value of depth of the deeper recess 11 is 100%, the value of depth of the shallower recess 11 is preferred to be set within a range of 10 to 95% or 50 to 90%.

In the recess 11 of the substrate 10, its side surface 11b is preferred to be provided with a taper angle. For example, an angle θ formed by the bottom surface 11a and the side surface 11b of the recess 11 is preferred to be 91 to 100 degrees or 92 to 95 degrees. In view of this, the circuit element 20 is easily disposed in the recess 11. Also, after molding the thermosetting resin into a predetermined shape of the substrate 10 using a metallic mold, the completed substrate 10 is easily removed from the metallic mold.

The substrate 10 may be provided with through-holes 12 that pass through from a front surface to a back surface in order to obtain a conduction between the front surface and the back surface. The through-hole 12 may be formed together with the recess on the substrate when the substrate with the recess is molded by a mold construction method as described later. The through-hole 12 can also be drilled at any desired position of the substrate 10 using, for example, a drill, punching, etching, sand-blasting, and a laser.

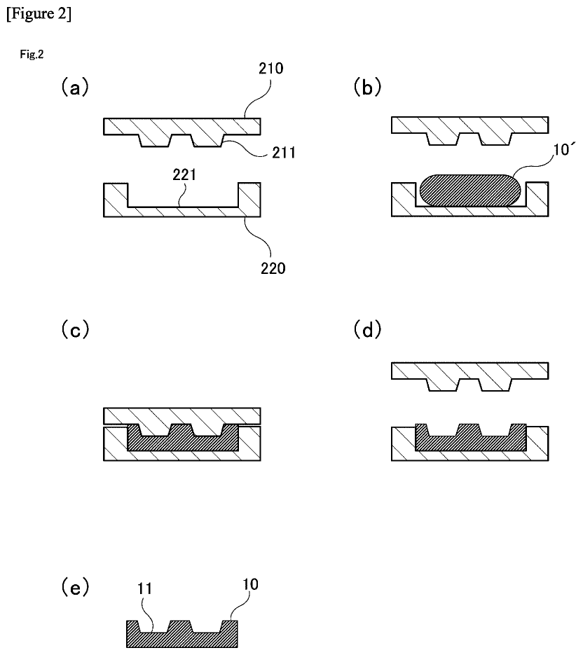

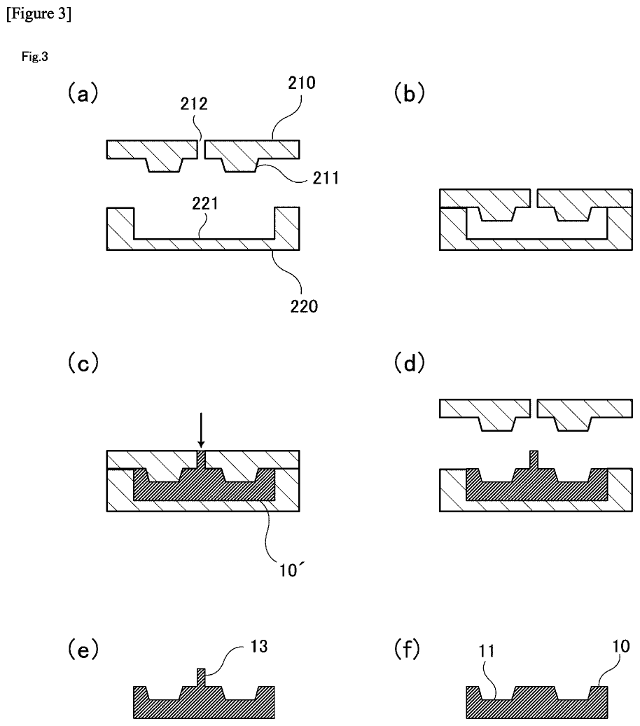

Although the method for producing the substrate 10 is not particularly limited, particularly, molding by the compression method as illustrated in FIG. 2 or the mold construction method, such as a transfer method, as illustrated in FIG. 3 is preferred to obtain the substrate 10 with the recess 11. It is also possible to form the through-hole 12 simultaneously with the recess 11 on the substrate 10.

In the compression method, as illustrated in FIG. 2, first, a thermosetting resin 10′ before curing is filled between an upper metallic mold 210 having a protrusion portion 211 and a lower metallic mold 220 having a depression portion 221. The protrusion portion 211 of the upper metallic mold 210 has a pattern corresponding to a pattern of the recess 11 of the substrate 10 that is to be finally obtained. Accordingly, pressurizing the thermosetting resin 10′ with the upper metallic mold 210 and the lower metallic mold 220 ensures obtaining the thermosetting resin 10′ having the recess molded into a predetermined shape. Then, heating this thermosetting resin 10′ after molding ensures obtaining the substrate 10 formed of the cured thermosetting resin. Note that, heating and pressurizing the thermosetting resin 10′ may be performed simultaneously or may be performed in different processes.

In the transfer method, as illustrated in FIG. 3, first, the upper metallic mold 210 having the protrusion portion 211 and an injection port 212 is fit to the lower metallic mold 220 having the depression portion 221 to form a space that corresponds to a shape of the substrate 10 that is to be finally obtained between the upper metallic mold 210 and the lower metallic mold 220. Then, the thermosetting resin 10′ before curing is injected inside the above-described space via the injection port 212 of the upper metallic mold 210. The pattern of the protrusion portion 211 of the upper metallic mold 210 corresponds to the pattern of the recess 11 of the substrate 10 that is to be finally obtained. Thereafter, heating the thermosetting resin 10′ with the lower metallic mold 220 and the upper metallic mold 210 closed ensures obtaining the substrate 10 formed by the cured thermosetting resin. The substrate 10 has a burr 13 corresponding to a shape of the injection port 212 of the upper metallic mold 210 left, and therefore, a process to cut off this burr 13 is performed. In view of this, the substrate 10 having any desired recess 11 can be obtained.

In the recesses 11 of the substrate 10, the respective circuit elements 20 are disposed. Examples of the circuit element 20 include a semiconductor chip and an electronic element. Examples of the semiconductor chip include a Large Scale Integration (LSI), an Integrated Circuit (IC), and a transistor. Examples of the electronic element includes a wireless antenna, an optical sensor, a condenser, a coil, and a resistive element. The circuit element 20 has electrode pads 21, and is electrically connected to the redistribution layers 40 via these electrode pads 21. As illustrated in FIG. 1(a), the circuit element 20 is only necessary to be disposed such that the electrode pads 21 are located on a side of the opening of the recess 11. At this time, the main body of the circuit element 20 is wholly housed in the recess 11, and it is preferred that only the electrode pad 21 is exposed from the opening of the recess 11. The circuit element 20 is preferred to be joined on the bottom surface 11a of the recess 11 using a known adhesive or the like.

Within the recesses 11 of the substrate 10, respective insulating layers 30 for sealing the circuit elements 20 are formed. The insulating layer 30 is configured of, for example, an insulating material, such as a known mold resin and ceramic. For example, after joining the circuit element 20 in the recess 11 of the substrate 10, a thermosetting mold resin (uncured) is filled within this recess 11, and thereafter performing the thermosetting process ensures sealing the circuit element 20 within the mold resin. Disposing the circuit element 20 within the recess 11 ensures avoiding the occurrence of the positional shift of the circuit element 20 when the mold resin is filled.

On the opening side of the recess 11 of the substrate 10, the redistribution layer 40 is formed, and the electrode pad 21 of the circuit element 20 is connected to this redistribution layer 40. The redistribution layer 40 electrically connects any desired circuit elements 20, and this forms an electric circuit. A known method is simply used for the method for forming the redistribution layer 40. For example, the redistribution layer 40 may be formed by forming a plating resist on a surface of the substrate 10 to form a resist pattern to have an opening in a predetermined wiring shape, and thereafter, forming a seed layer or the like, and performing an electrolytic plating process or an electroless plating process. Solder balls may be mounted on the redistribution layer 40. The solder ball can be connected to, for example, a package substrate (not illustrated).

A conductor material is filled in the through-hole 12 of the substrate 10, and this forms a through-via 50. For the conductor material, a material having known electrical conductivity and thermal conductivity, such as metal, can be employed. Examples of the conductor material include copper, silver, aluminum, and the like. Forming the through-via 50 ensures connecting the wafers in a vertical direction via the conductor material, and thus, a plurality of the semiconductor chips can be three-dimensionally integrated.

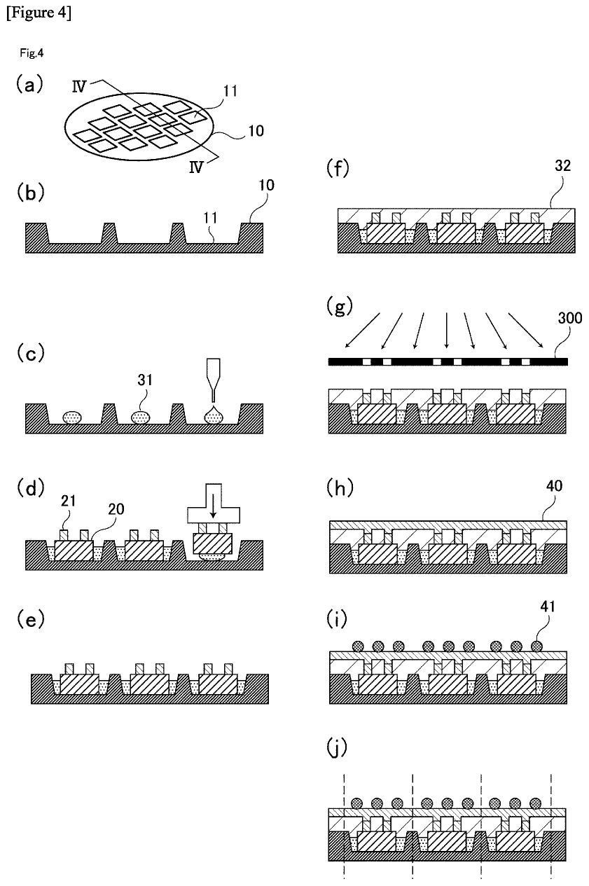

Next, with reference to FIG. 4, a process of producing the semiconductor device 100 will be described. FIG. 4(a) illustrates a planar shape of the substrate 10, and FIG. 4(b) illustrates a cross-sectional structure along IV-IV. As illustrated in FIGS. 4(a) and (b), first, the substrate 10 having the predetermined recesses 11 is prepared. As the production process of the substrate 10, as described above, it is preferred to employ a molding process, such as the compression method (see FIG. 2) and the transfer method (see FIG. 3).

Next, as illustrated in FIG. 4(c), adhesive agents 31 are applied in the recesses 11 of the substrate 10. This adhesive agent 31 is used for a usage of joining the circuit element 20 in the recess 11 of the substrate 10. In order to cause the adhesive agent 31 to function as an insulating layer, it is preferred to use one with insulating property as this adhesive agent 31. The adhesive agents with insulating property can include, for example, resin-based adhesive agents of, for example, an epoxy resin, a silicone resin, and an acrylic resin.

Note that, for the adhesive agent 31, it is not limited to the one with insulating property, but one with conductive property may be used. The adhesive agents 31 with conductive property include, for example, a conductive paste containing metal powders. Use of the conductive adhesive agent ensures a conduction from the back surface of the circuit element 20. Filling the conductive adhesive in the peripheral area of the circuit element 20 ensures obtaining high thermal conductive property.

Next, as illustrated in FIG. 4(d), any desired circuit elements 20 are disposed in the recesses 11 of the substrate 10, and the circuit elements 20 and the substrate 10 are joined with the adhesive agents 31. At this time, insertion of the circuit element 20 in the recess 11 spreads the adhesive agent 31 within the recess 11 and forms an insulating layer in the peripheral area of the circuit element 20.

Next, as illustrated in FIG. 4(e), the substrate 10 is heated to cure the adhesive agents 31.

Next, as illustrated in FIG. 4(f), a photosensitive resin film 32 is formed on the substrate 10 and the circuit elements 20. As the photosensitive resin film 32, a photoresist, a resist ink, a dry film, and the like can be used. Methods for forming the photosensitive resin film 32 can include, for example, a method in which a resin sheet formed of, for example, a photosensitive resin composition is laminated on the substrate 10 by thermocompression bonding or the like. Note that, a non-photosensitive resin film can also be used instead of the photosensitive resin film 32.

Next, as illustrated in FIG. 4(g), predetermined openings are formed for the photosensitive resin film 32, and the electrode pads 21 of the circuit elements 20 of the substrate 10 are exposed from the openings. Methods for forming the openings can include, for example, a method in which the photosensitive resin film 32 is exposed using a mask sheet 300 corresponding to a pattern of the openings (an exposure and development method). When non-photosensitive resin film is used instead of the photosensitive resin film 32, the openings can be formed by laser processing and the like.

Next, as illustrated in FIG. 4(h), a metallic film is disposed on a surface of the photosensitive resin film 32 to form the redistribution layer 40. The redistribution layer 40 also buries the openings of the photosensitive resin film 32, and thus, the circuit elements 20 are connected to the redistribution layer 40. The redistribution layer 40 is simply formed by a known method, such as the electroless plating method and the plating method. As the redistribution layer 40, a conductive material, such as copper, copper alloy, 42 Alloy, nickel, iron, chrome, tungsten, gold, and solder, can be used. Next, as illustrated in FIG. 4(i), solder balls 41 may be mounted on the redistribution layer 40.

Next, as illustrated in FIG. 4(j), using a known dicing saw, the substrate 10 is diced into any desired size. The direction of dicing may be only any one of an x-direction and a y-direction in a planar direction, or may be both of the x-direction and the y-direction. In view of this, the substrate 10 including the circuit elements 20 is diced into any desired sized ones.

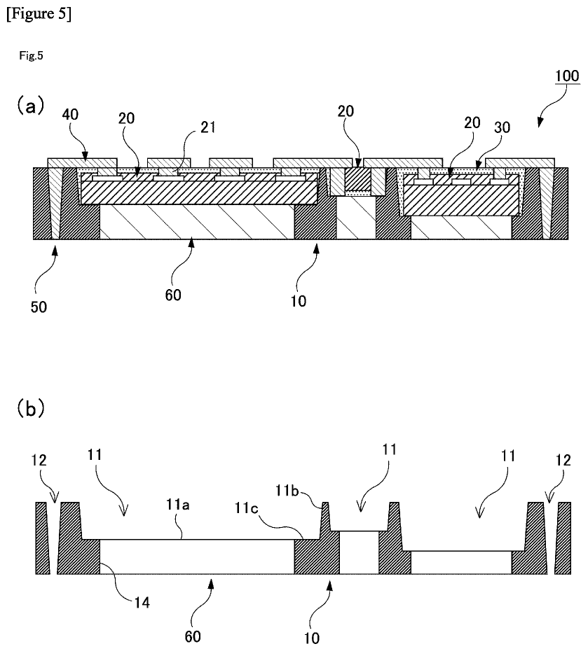

Next, FIG. 5 illustrates a modification of the semiconductor device 100 according to the first embodiment illustrated in FIG. 1. While the semiconductor device 100 illustrated in FIG. 5 basically has the same configuration as the one illustrated in FIG. 1, it is different in that hole portions 14 are formed in the substrate 10, and conductor materials 60 are filled in the hole portions 14.

As illustrated in FIG. 5, the hole portions 14 are formed within the recesses 11 of the substrate 10. The hole portion 14 has an opening area smaller than the bottom surface 11a of the recess 11. Accordingly, the bottom surface 11a of the recess 11 has a portion other than the hole portion 14 serving as step portions 11c. When the circuit element 20 is disposed in the recess 11 of the substrate 10, a main body part of the circuit element 20 abuts on the step portions 11c of the recess 11 to keep it from falling into the hole portion 14.

As the conductor material 60 filled within the hole portion 14, a material that has both or at least one of conductive property and thermal conductivity is used. Examples of the conductor material 60 include a metallic material, such as copper, silver, aluminum, and the like. The conductor material 60 filled in the hole portion 14 is directly in contact with the circuit element 20 to play a role to release the heat emitted from the circuit element 20 or electrically connect the circuit element 20 to another circuit. In the example illustrated in FIG. 5, the conductor material 60 is mainly used as a heat dissipation member. In order to enhance the heat dissipation effect by the conductor material 60, it is preferred to expand the contacted area between the circuit element 20 and the conductor material 60.

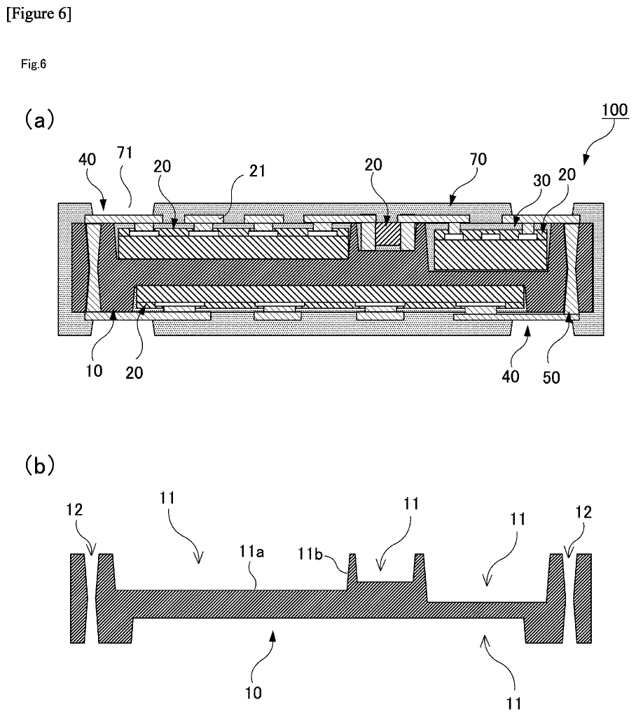

Next, with reference to FIG. 6, a second embodiment of the semiconductor device 100 according to the present invention will be described. The second embodiment illustrated in FIG. 6 is different mainly in that the recesses 11 are formed on both the front and back surfaces of the substrate 10 compared with the first embodiment illustrated in FIG. 1. Regarding the semiconductor device 100 according to the second embodiment, the same configurations as the first embodiment are attached by the same reference numerals.

As illustrated in FIG. 6, the recesses 11 can be formed on both of the front surface (a first surface) and the back surface (a second surface) of the substrate 10 of the semiconductor device 100. In the plurality of recesses 11 formed on the front surface and the back surface of the substrate 10, the respective circuit elements 20 are disposed similarly to the first embodiment.

The redistribution layers 40 are formed on the front surface and the back surface of the substrate 10, and the circuit elements 20 on each of the surfaces are electrically connect to the redistribution layers 40. The through-vias 50 are provided from the front surface over to the back surface of the substrate 10, and this through-via 50 electrically connects the redistribution layer 40 on the front surface of the substrate 10 to the redistribution layer 40 on the back surface. In view of this, electric circuits are established on both surfaces of the substrate 10.

In the second embodiment, insulating films 70 are formed so as to cover the redistribution layers 40 on both surfaces of the substrate 10. The insulating film 70 almost entirely covers the semiconductor device 100 except for a part of openings 71. The opening 71 of the insulating film 70 is disposed so as to expose metallic materials that constitute the redistribution layers 40 on the front surface and/or the back surface of the substrate 10. Accordingly, another semiconductor device or circuit element can be connected to the redistribution layer 40 via the opening 71 of the insulating film 70.

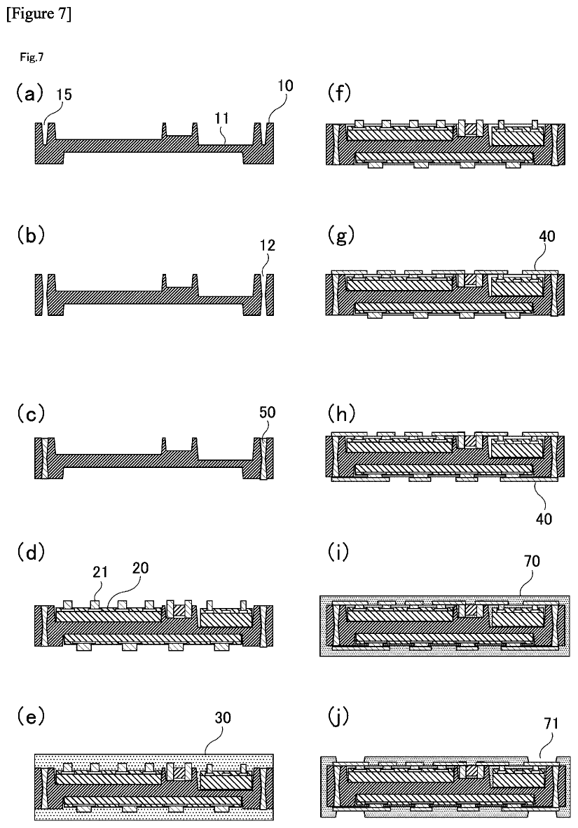

FIG. 7 illustrates an exemplary production process of the semiconductor device 100 according to the second embodiment. As illustrated in FIG. 7(a), first, the substrate 10 having the front surface and the back surface on which the recesses 11 are formed is prepared. The method for forming the substrate 10 may be performed in compliant with the compression method illustrated in FIG. 2 or the transfer method illustrated in FIG. 3. In the example illustrated in FIG. 7(a), recesses 15 for forming through-holes are disposed on the front surface (the first surface) of the substrate 10 besides the recesses 11 for disposing the circuit elements 20. This recess 15 for the through-hole can be obtained by molding the thermosetting resin similarly to other recesses 11.

Next, as illustrated in FIG. 7(b), the through-holes 12 are formed by excavating portions corresponding to the recesses 15 for the through-holes of the substrate 10. At this time, when the recesses 15 for the through-holes are disposed on the front surface side of the substrate 10, it is preferred to perform the drilling process or the laser process from the back surface side of the substrate 10 to cause these recesses 15 for the through-holes to be the through-holes 12. When it is attempted to form the through-hole 12 only from one surface side of the substrate 10, there is a problem that the through-hole 12 is gradually tapered off. That is, when the through-hole 12 is formed on the substrate 10 by drill or laser, the deeper the position of the through-hole 12 is, the narrower the open hole diameter becomes in a tapered manner. Accordingly, decreasing the open hole diameter of the through-hole 12 has a problem of a conduction failure between upper and lower semiconductor devices or their lowered reliability. In particular, the thicker the thickness of the substrate 10 gets, the more significant this problem becomes. Therefore, in the embodiment, the recesses 15 for the through-holes are formed on the front surface of the substrate 10, and thereafter, the drilling process or the laser process is performed from the back surface side of the substrate 10 to drill the through-holes 12 at positions corresponding to the recesses 15 for the through-holes. Thus, sequentially drilling holes from both surfaces of the substrate 10 avoids the problem of decreased hole diameter of the through-hole 12.

Next, as illustrated in FIG. 7(c), the through-vias 50 are formed by filling the conductor material in the through-hole 12 of the substrate 10. The filling of the conductor material may be performed from any side of the front surface side or the back surface side of the substrate 10.

Next, as illustrated in FIG. 7(d), the adhesive agents are applied in the recesses 11 of the substrate 10 to join any desired circuit elements 20 in the recesses 11. In order to cause the adhesive agent to function as the insulating layer, it is preferred to use one with insulating property for this adhesive agent. Thereafter, in order to cure the adhesive agent, the heating process is performed on the substrate 10.

Next, as illustrated in FIG. 7(e), applying the insulating layers 30 (the mold resin) on both the front surface and the back surface of the substrate 10 to perform resin sealing of the circuit element 20. The insulating layer 30 is only necessary to have a thickness sufficient to be able to entirely cover the circuit elements 20 and the electrode pads 21 disposed in the recesses 11 of the substrate 10.

Next, as illustrated in FIG. 7(f), the electrode pads 21 of the circuit elements 20 are exposed by cutting the front surface of the insulating layer 30. The cutting methods include a method in which the insulating layer (in particular, one formed of a photosensitive resin film) is exposed using a mask sheet having an opening pattern corresponding to the electrode pads 21 and a method in which the insulating layer 30 is cut along the electrode pads 21 by laser process.

Next, as illustrated in FIG. 7(g) and FIG. 7(h), metal films are disposed on the surfaces of the insulating layers 30 to form the redistribution layers 40 for electrically connecting each of the circuit elements 20. The redistribution layers 40 are simply formed by a known method, such as the electroless plating method and the plating method.

Next, as illustrated in FIG. 7(i), the insulating film 70 is formed so as to cover the whole semiconductor device. Thereafter, as illustrated in FIG. 7(j), the openings 71 are formed at parts of the insulating film 70, and a metallic material that constitutes the redistribution layers 40 disposed on the front surface and the back surface of the substrate 10 are exposed from the openings 71. This ensures obtaining a semiconductor device with high degree of integration having the circuit elements 20 disposed on both surfaces of the substrate 10.

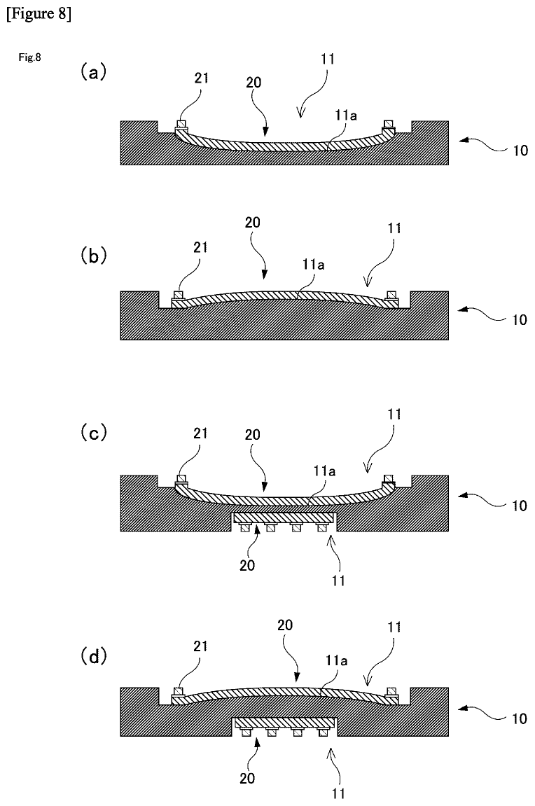

Next, with reference to FIG. 8, another modification example of the semiconductor device will be described. In particular, FIG. 8 illustrates a cross-sectional structure of the substrate 10 and the circuit elements 20.

In the example illustrated in FIG. 8(a), at least a part of the bottom surface 11a of the recess 11 of the substrate 10 is formed into a curved surface shape depressed into a recessed shape. The curved surface is only necessary to have a curved cross-sectional surface, and can take a form of a hemisphere surface or a parabolic-curved surface. On the recessed shaped bottom surface 11a, the circuit element 20 is disposed along its curved surface. When the bottom surface 11a of the recess 11 is in the recessed curved surface, it is preferred to use an element for transmitting and receiving a radio wave, such as a wireless antenna, as the circuit element 20. Since the recessed curved surface acts like a parabola antenna, transmitting and receiving sensitivity can be enhanced in the wireless antenna.

In the example illustrated in FIG. 8(b), at least a part of the bottom surface 11a of the recess 11 of the substrate 10 is formed into a curved surface shape raising into a projected shape. On the projected bottom surface 11a, the circuit element 20 is disposed along the curved surface. When the bottom surface 11a of the recess 11 is the projected curved surface, it is preferred to use an element for sensing, such as an optical sensor, as the circuit element 20. The optical sensor is mainly used for detecting a visible light ray and an infrared ray. The optical sensor collects the visible light ray and the infrared ray with a lens, and obtains a shape and the like of an imaging target as image data. Disposing the optical sensor on the projected curved surface radially expands its sensing direction, thereby ensuring an enlarged detection area and an improved sensor sensitivity.

FIG. 8(c) and FIG. 8(b) illustrate each of examples in which the recess 11 including the recessed or projected curved surface shaped bottom surface 11a is disposed on the front surface of the substrate 10 and the recess 11 having the bottom surface 11a in the planar shape is disposed on the back surface of the substrate 10. Thus, it is also possible to make the recess 11 on one surface of the substrate 10 into a curved surface shape and the recess 11 on the opposite surface into a planar shape. On the recess 11 having the bottom surface 11a on the planar surface, the semiconductor chip and another electrical element are simply disposed.

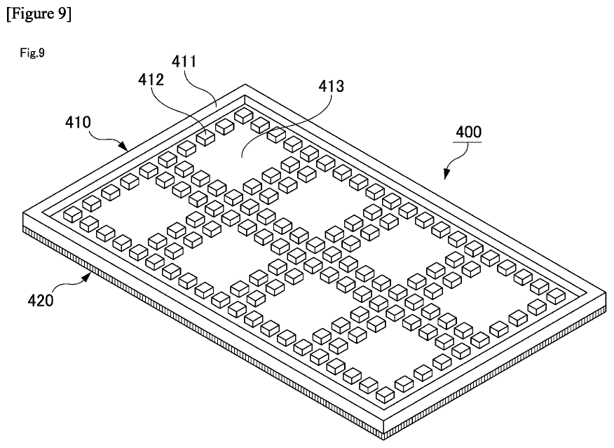

Next, with reference to FIG. 9 to FIG. 11, another example of the production process of the substrate 10 will be described. In this production process, a plate member 400 having a structure illustrated in, for example, FIG. 9 is used. The plate member 400 includes a metal layer 410 formed of a metallic material, such as copper and silver, and a resin layer 420 disposed on the back surface side of this metal layer 410. Note that, the resin layer 420 functions as a support member when the metal layer 410 is processed, and is not essential for the plate member 400. That is, the plate member 400 may be made only of the metal layer 410.

As illustrated in FIG. 9, the metal layer 410 has a front surface side on which unevenness of a predetermined pattern is formed by, for example, etching process or laser process. Specifically describing, the metal layer 410 has an outer frame portion 411 provided along its outer edge and a plurality of projecting portions 412 provided in a region inside the outer frame portion 411, and the region other than these outer frame portion 411 or projecting portions 412 is a depressed region. Note that, the outer frame portion 411 and the projecting portions 412 are only necessary to have similar heights. While the projecting portion 412 is formed into a quadrangular prism shape, it may be in a columnar shape, a triangular prism shape, and a polygonal-prismatic shape other than the quadrangular prism shape. In this embodiment, the projecting portions 412 are disposed at a certain pitch in a lateral direction and in a vertical direction. The metal layer 410 has a front surface on which a plurality of surrounded regions 413 with its peripheral area surrounded by the plurality of the projecting portions 412 are provided. This surrounded region 413 is a portion for forming the recess 11 of the substrate 10 as described later. Accordingly, the surrounded region 413 is preferred to secure an area enough to allow disposing the circuit element.

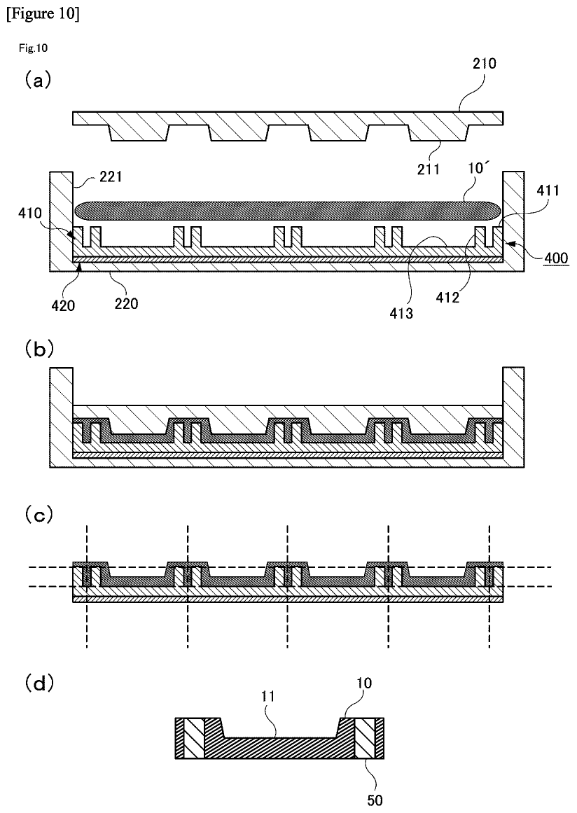

FIG. 10 illustrates an exemplary process for producing the substrate 10 using the above-described plate member 400. First, as illustrated in FIG. 10(a), the plate member 400 is disposed between the upper metallic mold 210 having the protrusion portions 211 and the lower metallic mold 220 having the depression portion 221. At this time, positioning is performed such that the surrounded regions 413 of the plate member 400 are positioned immediately below the protrusion portions 211 of the upper metallic mold 210. Thereafter, on the plate member 400, the thermosetting resin 10′ before curing is filled.

Next, as illustrated in FIG. 10(b), the thermosetting resin 10′ is pressurized by the upper metallic mold 210 and the lower metallic mold 220 to press-fit this thermosetting resin 10′ into the depressions on the surface of the plate member 400. In view of this, the thermosetting resin 10′ is shaped into a shape corresponding to the depressions on the surface of the plate member 400. Furthermore, since the protrusion portions 211 are disposed on the upper metallic mold 210 at positions corresponding to the surrounded regions 413 of the plate member 400, pressing the thermosetting resin 10′ by the upper metallic mold 210 forms the recesses 11 in the thermosetting resin 10′ within these surrounded regions 413. Thereafter, the thermosetting resin 10′ is heated and cured.

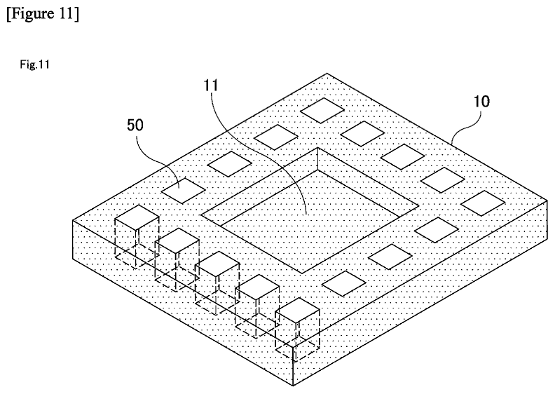

Next, as illustrated in FIG. 10(c), the cured thermosetting resin protruded out to the front surface side of the plate member 411 is polished to expose the projecting portions 411, and the back surface side of the plate member 411 is polished to remove the bottom surface portion of the plate member 411 except for the resin layer 420 and the projecting portions 411. The outer frame portion 411 of the plate member 400 is cut off and the plate member 400 is cut between the projecting portions 412 defining the surrounded regions 413 to dice the substrate 10 into any desired size. In view of this, as illustrated in FIG. 10(d), the substrate 10 that has the recess 11 for disposing the circuit element and that has the projecting portions 411 of the plate member 411 functioning as the through-vias 50 is obtained. FIG. 11 illustrates a perspective view of the substrate 10 thus formed. As illustrated in FIG. 11, the substrate 10 is provided with the recess 11 at its central portion, and has a plurality of the through-vias 50 with conductive property formed to pass through in a thickness direction so as to surround the peripheral area of the recess 11. The substrate 10 thus formed can be used in the production method of the semiconductor device according to the above-described embodiments.

In the present description, the embodiments of the present invention have been described above by referring to the drawings to express the content of the present invention. However, the present invention is not limited to the above-described embodiments and encompasses changed forms and improved forms obvious for those skilled in the art based on the matters described in the present description.

### Industrial Applicability

The present invention may be preferably used in production of a semiconductor device.

### Description of Reference Signs

10 . . . substrate

10′ . . . thermosetting resin

11 . . . recess

11a . . . bottom surface

11b . . . side surface

11c . . . step portion

12 . . . through-hole

13 . . . burr

14 . . . hole portion

15 . . . recess for through-hole

20 . . . circuit element

21 . . . electrode pad

30 . . . insulating layer

31 . . . adhesive agent

32 . . . photosensitive resin film

40 . . . redistribution layer

41 . . . solder ball

50 . . . through-via

60 . . . conductor material

70 . . . insulating film

71 . . . opening

100 . . . semiconductor device

210 . . . upper metallic mold

211 . . . protrusion portion

212 . . . injection port

220 . . . lower metallic mold

221 . . . depression portion

300 . . . mask sheet

400 . . . plate member

410 . . . metal layer

411 . . . outer frame portion

412 . . . projecting portion

413 . . . surrounded region

420 . . . resin layer

1. A semiconductor device comprising:
a substrate formed of a cured thermosetting resin and having one or a plurality of recesses;
a circuit element disposed in the recess of the substrate; and
a redistribution layer connected to the circuit element on an opening side of the recess.

2. The semiconductor device according to claim 1, wherein
the substrate has the plurality of recesses having different depths.

3. The semiconductor device according to claim 1, wherein
the substrate has a first surface and a second surface, and the recesses are formed on both the first surface and the second surface.

4. The semiconductor device according to claim 1, wherein
at least one of the recesses has a bottom surface thereof formed into a recessed curved surface.

5. The semiconductor device according to claim 4, wherein
a wireless antenna or an optical sensor is disposed in the recess having the bottom surface formed into the recessed curved surface, as the circuit element.

6. The semiconductor device according to claim 1, wherein
at least one of the recesses has a bottom surface thereof formed into a projected curved surface.

7. The semiconductor device according to claim 6, wherein
a wireless antenna or an optical sensor is disposed in the recess having the bottom surface formed into the projected curved surface, as the circuit element.

8. The semiconductor device according to claim 1, wherein
the substrate has a conductor material disposed in the recess such that the conductor material passes through in a thickness direction of the substrate.

9. The semiconductor device according to claim 1, wherein
the substrate has a conductor material disposed in a peripheral area of the recess such that the conductor material passes through in a thickness direction of the substrate.

10. The semiconductor device according to claim 1, wherein
the thermosetting resin before curing has a thermal conductivity of 0.5 W/mk or more.

11. The semiconductor device according to claim 1, wherein
the thermosetting resin includes one or two or more of silica, alumina, aluminum nitride, and boron nitride.

12. A semiconductor device comprising:
a substrate formed of a cured thermosetting resin, wherein the substrate has a first surface and a second surface, wherein the substrate has one or a plurality of recesses formed on both the first surface and the second surface;
circuit elements disposed in the recesses on both the first surface and the second surface;
redistribution layers connected to the circuit elements on opening sides of the recesses on both the first surface and the second surface; and
a through-via passing through the substrate in a thickness direction in peripheral areas of the recesses,
wherein the redistribution layers on the first surface and the second surface are electrically connected via the through-via.

13. A method for producing a semiconductor device, comprising:
a step of forming a substrate by heat-curing a thermosetting resin after molding the thermosetting resin into a shape having one or a plurality of recesses;
a step of disposing a circuit element in the recess of the substrate; and
a step of connecting a redistribution layer to the circuit element on an opening side of the recess.

14. The semiconductor device production method according to claim 13, wherein
in the step of disposing the circuit element, an adhesive agent with insulating property is disposed in the recess or on the circuit element to join the substrate and the circuit element with the adhesive agent.

15. The semiconductor device production method according to claim 13, wherein
in the step of disposing the circuit element, an adhesive agent with conductive property is disposed in the recess or on the circuit element to join the substrate and the circuit element with the adhesive agent.

16. The semiconductor device production method according to claim 13, further comprising
a step of causing at least one of the recesses to make a through-hole by drilling the substrate from a second surface side on an opposite side of a first surface on which the recess of the substrate is disposed.

17. The semiconductor device production method according to claim 13, wherein
the step of forming the substrate is a step of forming the substrate by heat-curing a thermosetting resin after molding the thermosetting resin into a shape having one or a plurality of recesses and one or a plurality of through-holes.

18. The semiconductor device production method according to claim 13, wherein
the step of forming the substrate brings a thermosetting resin into pressure contact with a surface of a plate member having a projecting portion with conductive property, heat-cures the thermosetting resin with the thermosetting resin surrounding a peripheral area of the projecting portion, and cuts off a portion excluding the projecting portion of the plate member, so as to cause the projecting portion to function as a through-via passing through the substrate made of the thermosetting resin in a thickness direction.

19. The semiconductor device production method according to claim 13, wherein
the thermosetting resin before curing has a thermal conductivity of 0.5 W/mk or more.

20. The semiconductor device production method according to claim 13, wherein
the thermosetting resin includes one or two or more of silica, alumina, aluminum nitride, and boron nitride.
